(19) United States
(12) Patent Application Publication
(10) Pub. No.: US 2012/0112805 A1
(43) Pub. Date: May 10, 2012

(54) PHASE-FREQUENCY DETECTOR

(75) Inventor: Nak Won LEE, Seoul (KR)

(73) Assignee: HYNIX SEMICONDUCTOR INC., Icheon-si (KR)

(21) Appl. No.: 13/293,280

(22) Filed: Nov. 10, 2011

(30) Foreign Application Priority Data
Nov. 10, 2010 (KR) 10-2010-0111662

(51) Int. Cl. H03L 7/00

(52) U.S. Cl. 327/142

(57) ABSTRACT

A phase-frequency detector includes an up signal generating unit and a down signal generating unit. The up signal generating unit is configured to evaluate a first node to generate an up signal, precharge the first node in response to a first clock, and reset the first node in response to the first clock, the up signal, and a down signal. The down signal generating unit is configured to evaluate a second node to generate a down signal, precharge the second node in response to a second clock, and reset the second node in response to the second clock, the up signal, and the down signal.

### CROSS-REFERENCE TO RELATED APPLICATIONS

This application claims priority to Korean Patent Application No. 10-2010-0111662 filed on Nov. 10, 2010, in the Korean Intellectual Property Office, the disclosure of which is incorporated herein by reference in its entirety.

### BACKGROUND OF THE INVENTION

1. Field of the Invention

The present invention relates generally to a phase-frequency detector.

2. Description of the Related Art

A phase-frequency detector (PFD) compares two input clocks and outputs the phase and frequency differences between them. Phase-frequency detectors are used for synchronizing the phases and frequencies of an input clock and a feedback clock in various applications such as phase-locked loops (PLL), delay locked loops (DLL), clock data recovery (CDR) circuits, etc.

A phase frequency detector may be a NAND-type static phase-frequency detector or a precharge-type dynamic phase-frequency detector.

A NAND-type static phase-frequency detector is operated based on an edge-trigger scheme. Therefore, there is no limitation to an input duty cycle, and the detection gain is constant across the entire range of the phase error. However, a NAND-type static phase-frequency detector is not well equipped to support a high speed operation, because a dead zone is developed when the input and output phase differences are very small, and it would need a large number of logic gates to overcome the problem.

A precharge-type dynamic phase-frequency detector is configured with a small number of transistors and operable at a high speed. When the phase difference (Δθ) between a reference signal and a local signal is in a range of |π|<Δθ<|2π|, the phase sensitivity of the phase-frequency detector is fixed to a minimum or maximum value . This results in reduction of locking time and variations in the detection gain, which affect the loop stability of the phase-frequency detector.

A conventional precharge-type dynamic phase-frequency detector includes precharge and reset functions as a part of performing operations to compare and output the phase and frequency differences of two inputted clock signals. However, the conventional phase-frequency detector determines whether to reset the internal precharge nodes based only on the so-called up and down signals which leads to the precharge and reset operations being performed at the same time, and, as a result, the precharge nodes in the conventional precharge-type dynamic phase-frequency detector may end up in an unknown state and cause malfunctioning of the precharge-type dynamic phase-frequency detector.

### SUMMARY OF THE INVENTION

An aspect of the present invention provides a phase-frequency detector that is capable of preventing precharge nodes from having an unknown state.

According to an aspect of the present invention, there is provided a phase-frequency detector including: an up signal generating unit configured to evaluate a first node to generate an up signal, precharge the first node in response to a first clock, and reset the first node in response to the first clock, the up signal, and a down signal; and a down signal generating unit configured to evaluate a second node to generate a down signal, precharge the second node in response to a second clock, and reset the second node in response to the second clock, the up signal, and the down signal.

According to another aspect of the present invention, there is provided a phase-frequency detector including: a first pull-up unit configured to precharge a first node according to a first clock; a first pull-down unit configured to discharge the first node in response to the first clock, an up signal, and a down signal; an up signal generating unit configured to evaluate the first node to generate the up signal; a second pull-up unit configured to precharge a second node according to a second clock; a second pull-down unit configured to discharge the second node in response to the second clock, the up signal, and the down signal; and a down signal generating unit configured to evaluate the second node to generate the down signal.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a circuit diagram of a precharge-type dynamic phase-frequency detector that may malfunction due to a precharge node entering into an unknown state;

FIG. 2 is a waveform diagram explaining the operation of the precharge-type dynamic phase-frequency detector shown in FIG. 1;

FIG. 3 is a circuit diagram of a precharge-type dynamic phase-frequency detector according to an embodiment of the present invention; and

FIGS. 4A and 4B are waveform diagrams explaining the operation of the precharge-type dynamic phase-frequency detector according to an embodiment of the present invention.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the thicknesses of layers and regions may be exaggerated for clarity. Like reference numerals in the drawings denote like elements, and thus their description will be omitted.

Unless explicitly described to the contrary, the word “comprise” and variations such as “comprises” or “comprising,” will be understood to imply the inclusion of stated elements but not the exclusion of any other elements.

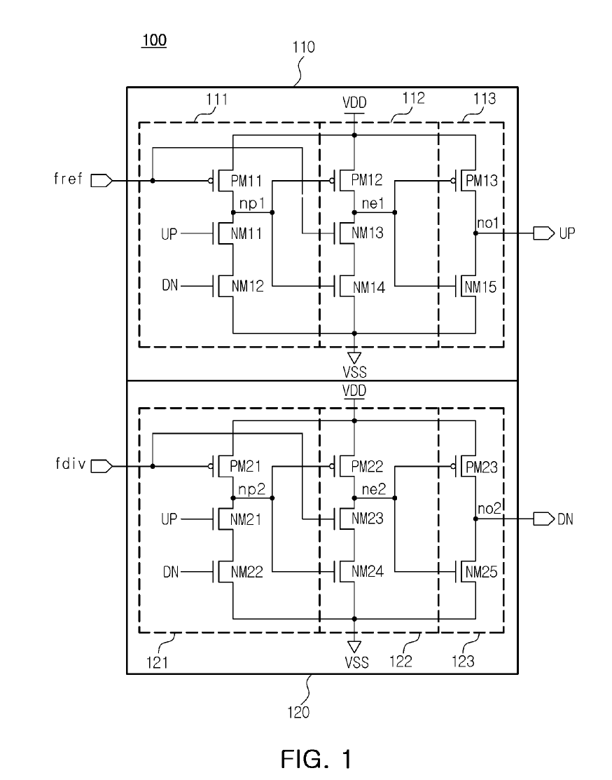

Referring to FIG. 1, shown therein is a precharge type dynamic phase-frequency detector 100 that may malfunction due to a precharge node entering into an unknown state. The precharge type dynamic phase-frequency detector 100 includes an up signal generating unit 110 and a down signal generating unit 120.

The up signal generating unit 110 is configured to update an up signal UP according to a reference signal fref and perform a reset operation by using the up signal UP and a down signal DN. The down signal generating unit 120 is configured to update the down signal DN according to a local signal fdiv and perform a reset operation by using the up signal UP and the down signal DN.

The up signal generating unit 110 includes a first sub circuit 111, a second sub circuit 112, and a third sub circuit 113.

The first sub circuit 111 of the up signal generating unit 110 is configured to (1) precharge a precharge node np1 according to the input signal fref or (2) reset the precharge node np1 according to the up signal UP and the down signal DN. The second sub circuit 112 is configured to evaluate the precharge node np1 and output an evaluation value to an evaluation node ne1. The third sub circuit 113 is configured to buffer the signal value of the evaluation node ne1 and generate an output signal UP.

Likewise, the down signal generating unit 120 includes a first sub circuit 121, a second sub circuit 122, and a third sub circuit 123.

The first sub circuit 121 of the down signal generating unit 120 is configured to (1) precharge a precharge node np2 according to the input signal fdiv or (2) reset the precharge node np2 according to the up signal UP and the down signal DN. The second sub circuit 122 is configured to evaluate the precharge node np2 and output an evaluation value to an evaluation node ne2. The third sub circuit 123 is configured to buffer a signal value of the evaluation node net and generate an output signal DN.

However, the phase-frequency detector 100 as shown in FIG. 1 determines whether to reset the precharge nodes np1 and np2 based on the up and down signals UP and DN, and the precharge nodes np1 and np2 may end up in an unknown state.

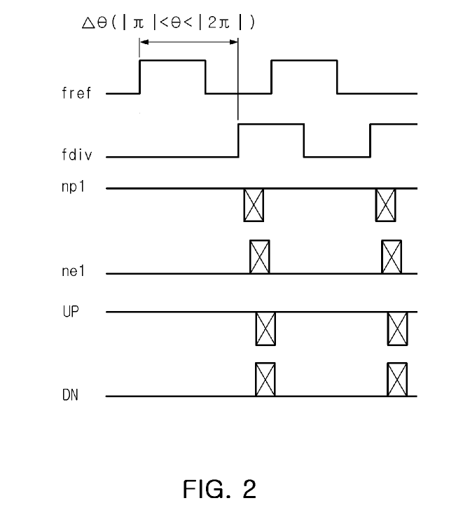

For example, now referring to FIG. 2, when the phase difference (Δθ) between the reference signal fref and the local signal fdiv is |π|<Δθ<|2π|, the phase-frequency detector 100 generates the up signal UP and the down signal DN having a high-level signal value within a low level duration of the reference signal fref or the local signal fdiv.

The first sub circuit 111 of the up signal generating unit 110 forms (1) a current path between a driving voltage VDD and the precharge node np1 and (2) a current path between the precharge node np1 and a ground voltage VSS at the same time. As a result, a precharge operation and a reset operation may end up being performed on the precharge node np1 at the same time; that is, the driving voltage VDD and the ground voltage VSS are simultaneously connected to the precharge node np1. Therefore, the precharge node np1 results in an unknown state for a predetermined period of time. This problem may also occur in the down signal generating unit 120.

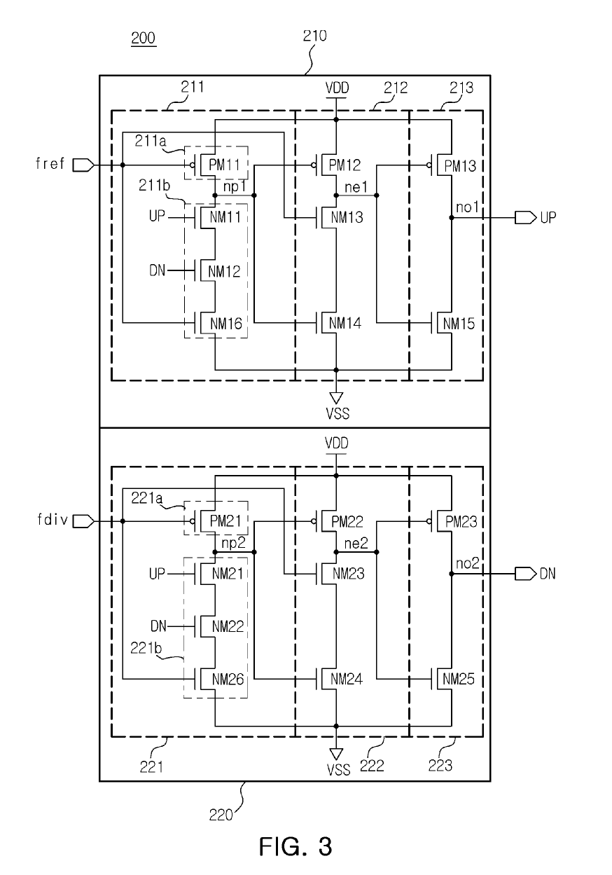

FIG. 3 is a circuit diagram of a precharge-type dynamic phase-frequency detector according to an embodiment of the present invention.

Referring to FIG. 3, the phase-frequency detector 200 according to an embodiment of the present invention includes an up signal generating unit 210 (also referred to as “the up unit”) and a down signal generating unit 220 (also referred to as “the down unit”).

The up signal generating unit 210 is configured to update an up signal UP according to a reference signal fref and perform a reset operation by using the reference signal fref, the up signal UP, and a down signal DN. The down signal generating unit 220 is configured to update the down signal DN according to a local signal fdiv and perform a reset operation by using the local signal fdiv, the up signal UP, and the down signal DN.

According to an embodiment of the present invention, the reset operation is performed after determining the necessity to perform a precharge operation by the reference signal fref and the local signal fdiv. More specifically, whether to perform a precharge operation on the precharge nodes np1 and np2 is determined using the reference signal fref and the local signal fdiv. When it is determined that a precharge operation needs to be performed, the reset operation on the precharge nodes np1 and np2 is prohibited. In this manner, the precharge nodes np1 and np2 are prevented from having an unknown state.

The up signal generating unit 210 and the down signal generating unit 220 may have a three-stage logic structure.

The up signal generating unit 210 (also referred to as “the up unit”) includes a first up unit sub circuit 211, a second up unit sub circuit 212, and a third up unit sub circuit 213.

The first up unit sub circuit 211 is configured to (1) precharge the up unit precharge node np1 according to its input signal fref or (2) reset the up unit precharge node np1 according to the input signal fref, the up signal UP, and the down signal DN. The second up unit sub circuit 212 is configured to evaluate the up unit precharge node np1 and output an evaluation value to the up unit evaluation node ne1. The third up unit sub circuit 213 is configured to buffer a signal value of the up unit evaluation node ne1 and generate an output signal UP.

The down signal generating unit 220 (also referred to as “the down unit”) includes a first down unit sub circuit 221, a second down unit sub circuit 222, and a third down unit sub circuit 223.

The first down unit sub circuit 221 is configured to (1) precharge the down unit precharge node np2 according to its input signal fdiv or (2) reset the down unit precharge node np2 according to the input signal fdiv, the up signal UP, and the down signal DN. The second down unit sub circuit 222 is configured to evaluate the down unit precharge node np2 and output an evaluation value to the down unit evaluation node ne2. The third down unit sub circuit 223 is configured to buffer a signal value of the down unit evaluation node net and generate an output signal DN.

The first up unit sub circuit 211 of the up signal generating unit 210 may include an up unit pull-up unit 211a and a up unit pull-down unit 211b. The up unit pull-up unit 211a may include a first up unit PMOS transistor PM11 configured to form a current path between a driving voltage VDD and the up unit precharge node np1 when the input signal fref has a low level. The up unit pull-down unit 211b may include first, second, and sixth up unit NMOS transistors NM11, NM12, NM16 configured to form a current path between the up unit precharge node np1 and a ground voltage VSS when all of the input signal fref, the up signal UP, and the down signal DN at a high level.

The first down unit sub circuit 221 of the down signal generating unit 220 may include a down unit pull-up unit 221a and a down unit pull-down unit 221b. The down unit pull-up unit 221a may include a first down unit PMOS transistor PM21 configured to form a current path between the driving voltage VDD and the down unit precharge node np2 when the input signal fdiv has a low level. The down unit pull-down unit 221b may include first, second, and sixth down unit NMOS transistors NM21, NM22, M26 configured to form a current path between the down unit precharge node np2 and the ground voltage VSS when all of the input signals fdiv, the up signal UP, and the down signal DN are at a high level.

According to an embodiment of the present invention, the up unit first sub circuit 211 of the up signal generating unit 210 may further include the sixth NMOS transistor NM16 configured to form a current path between the up unit precharge node np1 and the ground voltage VSS after determining whether to perform a precharge operation on the precharge node np1 using the input signal fref.

Likewise, according to an embodiment of the present invention, the down unit first sub circuit 221 of the down signal generating unit 220 may further include the down unit sixth NMOS transistor NM26 configured to form a current path between the down unit precharge node np2 and the ground voltage VSS after determining whether to perform a precharge operation on the down unit precharge node np2 using the input signal fdiv.

On the other hand, the second up unit sub circuit 212 of the up signal generating unit 210 may include a second up unit PMOS transistor PM12 and third and fourth up unit NMOS transistors NM13 and NM14. The second up unit PMOS transistor PM12 is configured to form a current path between the driving voltage VDD and the up unit evaluation node ne1 when the signal value of the up unit precharge node np1 has a low level. The third and fourth up unit NMOS transistors NM13 and NM14 are configured to form a current path between the up unit evaluation node ne1 and the ground voltage VSS when the input signal fref and the signal value of the precharge node np1 have a high level.

The second down unit sub circuit 222 of the down signal generating unit 220 may include a second down unit PMOS transistor PM22 and third and fourth down unit NMOS transistors NM23 and NM24. The second PMOS transistor PM22 is configured to form a current path between the driving voltage VDD and the down unit evaluation node net when the signal value of the down unit precharge node np2 has a low level. The third and fourth down unit NMOS transistors NM23 and NM24 are configured to form a current path between the down unit evaluation node net and the ground voltage VSS when the input signal fdiv and the signal value of the precharge node np2 have a high level.

The third up unit sub circuit 213 of the up signal generating unit 210 may include a third up unit PMOS transistor PM13 and a fifth up unit NMOS transistor NM15. The third up unit PMOS transistor PM13 is configured to form a current path between the driving voltage VDD and the up unit output node no1 when the signal value of the evaluation node ne1 has a low level. The fifth NMOS transistor NM15 is configured to form a current path between the up unit output node no1 and the ground voltage VSS when the signal value of the up unit evaluation node ne1 has a high level.

The third down unit sub circuit 223 of the down signal generating unit 220 may include a third down unit PMOS transistor PM23 and a fifth down unit NMOS transistor NM25. The third down unit PMOS transistor PM23 is configured to form a current path between the driving voltage VDD and the down unit output node not when the signal value of the down unit evaluation node net has a low level. The fifth down unit NMOS transistor NM25 is configured to form a current path between the down unit output node not and the ground voltage VSS when the signal value of the down unit evaluation node net has a high level.

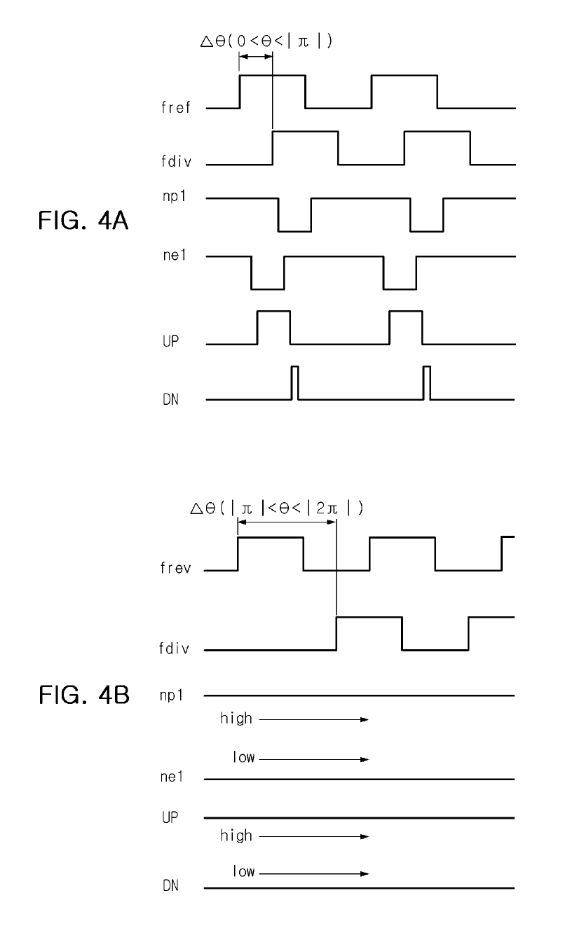

FIGS. 4A and 4B are waveform diagrams explaining the operation of the precharge-type dynamic phase-frequency detector as examples according to an embodiment of the present invention.

When the phase difference (Δθ) of the inputted reference signal fref and the local signal fdiv is 0<Δθ<|π|, the up signal generating unit 210 and the down signal generating unit 220 operates as follows according to an embodiment of the present invention.

The up signal generating unit 210 precharges the up unit precharge node np1 when the reference signal fref is at a low level. The signal value of the up unit precharge node np1 is evaluated when the reference signal fref changes to a high level, and the up signal UP is changed to a high level.

The down signal generating unit 220 receives the local signal fdiv having a phase difference (Δθ) of 0<Δθ<|π| with respect to the reference signal fref and changes the down signal DN to a high level in the same manner as the up signal generating unit 210.

Then, the up signal generating unit 210 forms a current path between the up unit precharge node np1 and the ground voltage VSS according to the reference signal fref, the up signal UP, and the down signal DN, which have a high-level signal value.

The down signal generating unit 220 also forms a current path between the down unit precharge node np2 and the ground voltage VSS according to the local signal fdiv, the up signal UP, and the down signal DN, which have a high-level signal value.

Accordingly, the down signal DN has a high-level signal value for a very short time. The up signal generating unit 210 and the down signal generating unit 220 reset or discharge the precharge respective nodes np1 and np2 during the high-level duration of the down signal DN. Therefore, the up signal UP and the down signal DN again change to a low level.

Then, if the reference signal fref and the local signal fdiv inputted to the up signal generating unit 210 and the down signal generating unit 220 respectively have a phase difference (Δθ) of 0<Δθ<|π| and again change to a low level, the up signal generating unit 210 and the down signal generating unit 220 repeat the precharge operation, the signal transition operation, and the reset operation as described above.

If the reference signal fref and the local signal fdiv are inputted with a phase difference (Δθ) of 0<Δθ<|π|, the high level duration of the up signal UP and the down signal DN is generated within the high level duration of the reference signal fref and the local signal fdiv. Therefore, the precharge operation and the reset operation on the respective precharge nodes np1 and np2 are performed independently.

Therefore, when the reference signal fref and the local signal fdiv are inputted with a phase difference (Δθ) of 0<Δθ<|π|, the unknown section of the respective precharge nodes np1 and np2 is not fundamentally generated.

When the phase difference (Δθ) between the reference signal fref and the local signal fdiv is |π|<Δθ<|2π51 , the up signal generating unit 210 and the down signal generating unit 220 operates as follows according to an embodiment of the present invention.

The up signal generating unit 210 and the down signal generating unit 220 generate the up signal UP and the down signal DN in the same manner as in the case of FIG. 4A. However, since the reference signal fref and the local signal fdiv have a phase difference (Δθ) of |π|<Δθ<|2π|, the high level duration of the up signal UP and the down signal DN is included in the low level duration of the reference signal fref.

In this case, if the up signal generating unit 210 controls the current path between the up unit precharge node np1 and the ground voltage VSS by using only the up signal UP and the down signal DN in the manner of the conventional art, the current path between the driving voltage VDD and the up unit precharge node np1 and the current path between the up unit precharge node np1 and the ground voltage VSS may be formed at the same time. That is, the precharge operation and the reset operation on the up unit precharge node np1 are performed at the same time, and the up unit precharge node np1 would end up in an unknown state.

However, the up signal generating unit 210 of FIG. 3 controls the current path between the up unit precharge node np1 and the ground voltage VSS by additionally using the reference signal fref, as well as the up signal UP and the down signal DN. That is, if the reference signal fref is at a low level and the precharge operation is performed on the up unit precharge node np1, the current path between the up unit precharge node np1 and the ground voltage VSS is forcibly cut off by the newly added sixth up unit NMOS transistor NM16. Therefore, the reset operation on the up unit precharge node np1 is prohibited while the precharge operation is performed on the up unit precharge node np1, thereby preventing the up unit precharge node np1 from having an unknown state.

In the same manner as described above, the down signal generating unit 220 prohibits the reset operation on the down unit precharge node np1 while the precharge operation is performed on the down unit precharge node np2 using the local signal fdiv, thereby preventing the down unit precharge node np2 from having an unknown state.

Moreover, in this case, the up signal UP continuously maintains a high-level signal value, and the down signal DN continuously maintains a low-level signal value.

Therefore, even in the case that the reference signal fref and the local signal fdiv are inputted with a phase difference (Δθ) of |π|<Δθ<|2π|, the phase-frequency detector prevents the occurrence of the unknown section in the respective precharge nodes np1 and np2.

The phase-frequency detector according to the exemplary embodiments of the present invention prevents the precharge nodes from having an unknown state and prevents unnecessary current consumption.

While the present invention has been shown and described in connection with the exemplary embodiments, it will be apparent to those skilled in the art that modifications and variations can be made without departing from the spirit and scope of the invention as defined by the appended claims.

What is claimed is:

1. A phase-frequency detector comprising:
an up signal generating unit configured to evaluate a first node to generate an up signal, precharge the first node in response to a first clock, and to reset the first node in response to the first clock, the up signal, and a down signal,
wherein the up signal generating unit is configured to determine whether to perform a precharge operation based at least on the signal status of the first clock and to prohibit a reset operation when the precharge operation is determined to be performed when the up signal generating unit has determined that a precharge operation needs to be performed.

2. The phase-frequency detector of claim 1, wherein the up signal generating unit comprises:
a first up unit sub circuit configured to precharge the first node in response to the first clock or reset the first node according to the first clock, the up signal, and the down signal;
a second up unit sub circuit configured to evaluate the first node and output an evaluation value to a third node; and
a third up unit sub circuit configured to buffer a signal value of the third node and generate the up signal.

3. The phase-frequency detector of claim 2, wherein the first up unit sub circuit comprises:
an up unit pull-up unit configured to precharge the first node according to the first clock; and
an up unit pull-down unit configured to discharge the first node according to the first clock, the up signal, and the down signal.

4. The phase-frequency detector of claim 1, further comprising:
a down signal generating unit configured to evaluate a second node to generate a down signal, precharge the second node in response to a second clock, and reset the second node in response to the second clock, the up signal, and the down signal,
wherein the down signal generating unit is configured to determine whether to perform a precharge operation based at least on the signal status of the second clock and to prohibit a reset operation when the precharge operation is determined to be performed when the down signal generating unit has determined that a precharge operation needs to be performed.

5. The phase-frequency detector of claim 4, wherein the down signal generating unit comprises:
a first down unit sub circuit configured to precharge the second node in response to the second clock, or reset the second node according to the second clock, the up signal, and the down signal;
a second down unit sub circuit configured to evaluate the second node and output an evaluation value to a fourth node; and
a third down unit sub circuit configured to buffer a signal value of the fourth node and generate the down signal.

6. The phase-frequency detector of claim 5, wherein the first sub circuit comprises:
a down unit pull-up unit configured to precharge the second node according to the second clock; and
a down unit pull-down unit configured to discharge the second node according to the second clock, the up signal, and the down signal.

7. A phase-frequency detector comprising:
a first pull-up unit configured to precharge a first node according to a first clock;
a first pull-down unit configured to discharge the first node in response to the first clock, an up signal, and a down signal;
an up signal generating unit configured to evaluate the first node to generate the up signal;
a second pull-up unit configured to precharge a second node according to a second clock;
a second pull-down unit configured to discharge the second node in response to the second clock, the up signal, and the down signal; and
a down signal generating unit configured to evaluate the second node to generate the down signal.
